(19) United States
(12) Patent Application Publication
(10) Pub. No.: US 2011/0141711 A1
(43) Pub. Date: Jun. 16, 2011

(54) ELECTRONIC COMPONENT EMBEDDED PRINTED CIRCUIT BOARD AND METHOD OF MANUFACTURING THE SAME

(75) Inventors: Seung-Hyun SOHN, Suwon-si (KR); Yul-Kyo Chung, Yongin-si (KR); Dae-Jung Byun, Saha-gu (KR); Moon-II Kim, Suwon-si (KR)

(73) Assignee: SAMSUNG ELECTRO-MECHANICS CO., LTD.

(21) Appl. No.: 12/967,585

(22) Filed: Dec. 14, 2010

(30) Foreign Application Priority Data
Dec. 14, 2009 (KR) 10-2009-0124029

(51) Int. Cl. H05K 1/18; H05K 3/30

(52) U.S. Cl. 361/760; 174/260; 29/832

(57) ABSTRACT

An electronic component embedded printed circuit board and a method of manufacture the same are disclosed. The electronic component embedded printed circuit board in accordance with an embodiment of the present invention can include a dielectric core substrate, which has a cavity formed therein, an electronic component, which is housed in the cavity and has an electrode formed on one surface thereof, an insulation layer, which is formed on both surface of the dielectric core substrate, a via, which is formed in the insulation layer such that the via is electrically connected to the electrode, and a first circuit pattern, which is formed on the insulation layer such that the first circuit pattern is electrically connected to the via.

### CROSS-REFERENCE TO RELATED APPLICATIONS

This application claims the benefit of Korean Patent Application No. 10-2009-0124029, filed with the Korean Intellectual Property Office on Dec. 14, 2009, the disclosure of which is incorporated herein by reference in its entirety.

### BACKGROUND

1. Technical Field

The present invention is related to an electronic component embedded printed circuit board and a method of manufacturing the electronic component embedded printed circuit board.

2. Description of the Related Art

With the widespread popularity of mobile terminals and laptop computers, electronic devices that require high-speed operation are becoming increasingly popular, and thus there is a growing demand for printed circuit boards capable of high-speed operation. For such high-speed operation, the wiring patterns and electronic components formed on a printed circuit board need to be highly densified.

Such high-density is achieved by a build-up method, and circuits are minutely formed by way of, for example, the SAP (Semi-Additive Process) and MSAP (Modified Semi-Additive Process). Meanwhile, embedded printed circuit boards that allow components, for example, resistors, capacitors and ICs, to be embedded in the printed circuit board have been developed.

For such advantages as reduction in the size of the board, added area for surface mounting, sufficient area of interconnection surface and decrease of impedance, there has been continuous demand for research and development in the embedded printed circuit boards.

### SUMMARY

The present invention provides an electronic component embedded printed circuit board and a method of manufacture the same that can simplify the manufacturing process and improve the yield.

An aspect of the present invention provides an electronic component embedded printed circuit board. The electronic component embedded printed circuit board in accordance with an embodiment of the present invention can include a dielectric core substrate, which has a cavity formed therein, an electronic component, which is housed in the cavity and has an electrode formed on one surface thereof, an insulation layer, which is formed on both surface of the dielectric core substrate, a via, which is formed in the insulation layer such that the via is electrically connected to the electrode, and a first circuit pattern, which is formed on the insulation layer such that the first circuit pattern is electrically connected to the via.

An aligning hole can be formed in the dielectric core substrate to align a position of the electronic component, and the cavity can be formed at predetermined regular intervals from a position of the aligning hole.

The electronic component embedded printed circuit board can further include a build-up layer, which is formed on the insulation layer, and a second circuit pattern, which is formed on the build-up layer in such a way that the second circuit pattern is electrically connected to the first circuit pattern.

The cavity and the electronic component can be provided as a plurality of cavities and a plurality of electronic components, and the plurality of electronic components can be housed in the plurality of cavities in such a way that the electrodes of some of the plurality of electronic components and the electrodes of the remaining electronic components are in opposite directions.

A thickness of the dielectric core substrate can be same as a thickness of the electronic component comprising the electrodes.

Another aspect of the present invention provides a method of manufacturing an electronic component embedded printed circuit board. The method in accordance with an embodiment of the present invention can include forming a cavity in a dielectric core substrate, housing an electronic component in the cavity, in which the electronic component has an electrode formed on one surface thereof, forming an insulation layer on both surfaces of the dielectric core substrate, respectively, forming a via in the insulation layer, in which the via is electrically connected to the electrode, and forming a first circuit pattern on the insulation layer, in which the first circuit pattern is electrically connected to the via.

The method can further include, before the forming of the cavity, forming an aligning hole in the dielectric core substrate, in which the aligning hole aligns a position of the electronic component. Here, the cavity can be formed at predetermined regular intervals from a position of the aligning hole.

The method can further include, after the forming of the first circuit pattern, forming a build-up layer on the insulation layer and forming a second circuit pattern on the build-up layer, in which the second circuit pattern is electrically connected to the first circuit pattern.

The cavity and the electronic component can be provided as a plurality of cavities and a plurality of electronic components, and the plurality of electronic components can be housed in the plurality of cavities in such a way that the electrodes of some of the plurality of electronic components and the electrodes of the remaining electronic components are in opposite directions.

A thickness of the dielectric core substrate can be same as a thickness of the electronic component comprising the electrodes.

The method can further include, between the forming of the cavity and the housing of the electronic component, laminating a supporting tape on one surface of the dielectric core substrate so as to cover the cavity. Here, the housing of the electronic component can be performed by stacking the electronic component on the supporting tape.

Additional aspects and advantages of the present invention will be set forth in part in the description which follows, and in part will be obvious from the description, or may be learned by practice of the invention.

### BRIEF DESCRIPTION OF THE DRAWINGS

FIG. 1 is a cross-sectional view of an embodiment of an electronic component embedded printed circuit board in accordance with an aspect of the present invention.

FIG. 2 is a flow diagram illustrating an embodiment of a manufacturing method of an electronic component embedded printed circuit board in accordance with another aspect of the present invention.

FIGS. 3 to 11 are cross-sectional views illustrating each respective manufacturing process of an embodiment of a manufacturing method of an electronic component embedded printed circuit board in accordance with another aspect of the present invention.

### DETAILED DESCRIPTION

An electronic component embedded printed circuit board and a method of manufacturing the same according to a certain embodiment of the present invention will be described below in more detail with reference to the accompanying drawings. Those components that are the same or are in correspondence are rendered the same reference numeral regardless of the figure number, and redundant descriptions are omitted.

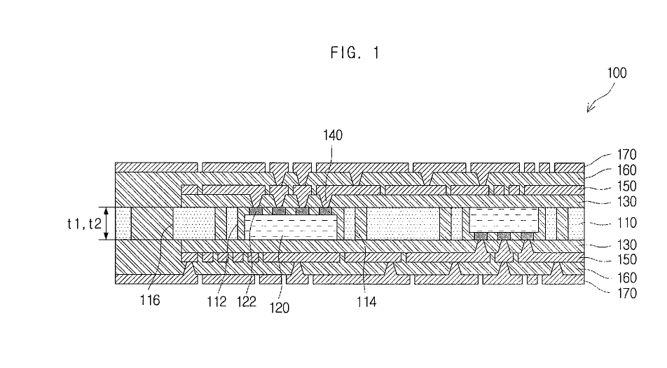

FIG. 1 is a cross-sectional view of an embodiment of an electronic component embedded printed circuit board 100 in accordance with an aspect of the present invention.

As illustrated in FIG. 1, the present embodiment of the present invention features an electronic component embedded printed circuit board 100 that includes a dielectric core substrate 110, an electronic component 120, an insulation layer 130, a via 140 and a first circuit pattern 150.

In this embodiment, since the dielectric core substrate 110 on which no copper layer is formed is used as a core layer, the wiring pattern layer that is unnecessarily thick as a result of using the conventional core layer stacked with a copper layer can be omitted. Accordingly, the manufacturing process can be simplified, and the yield can be improved.

Below, each component of the present embodiment will be described in more detail by referring to FIG. 1.

The dielectric core substrate 110 is the core of the electronic component embedded printed circuit board 100, and an unclad substrate, which has no copper layer formed on the surface, can be used as the dielectric core substrate 110, unlike the conventional core substrate. Specifically, as illustrated in FIG. 1, no copper layer is formed on the surface of the dielectric core substrate 110, and the insulation layer 130 can be laminated directly on the surface of the dielectric core substrate 110.

By using the dielectric core substrate 110 having no copper layer formed on the surface, the unnecessary wiring pattern layer can be omitted, and thus the electronic component embedded printed circuit board 100 can become thinner. Also, since the manufacturing process becomes simpler, the manufacturing cost and time can be saved.

As illustrated in FIG. 1, the dielectric core substrate 110 can have an aligning hole 114 for aligning the position of the electronic component 120, as well as a cavity 112 that is separated by a certain distance from the aligning hole 114. Also, as illustrated in FIG. 1, the dielectric core substrate 110 can also have a panel hole 116 for aligning the dielectric core substrate 110.

In this case, after the aligning hole 114 is first formed in the dielectric core substrate 110, the cavity 112 is formed at predetermined regular intervals from the aligning hole 114, as illustrated in FIG. 1. The cavity 112 can be provided as a plurality of cavities 112 in accordance with the number of the electronic component 120 to be embedded.

By setting the position of the cavity 112 with respect to the position of the aligning hole 114, the position of the cavity 112 can be precisely adjusted. Accordingly, the location accuracy of the electronic component 120 to be housed in the cavity 112 can be also improved.

As illustrated in FIG. 1, the electronic component 120 can be housed in the cavity 112, and an electrode 122 for electrical connection to the outside can be formed on one surface of the electronic component 120. The electrode 122 can be electrically connected to an external device through the via 140, the first circuit pattern 150 and a second circuit pattern 170.

Then, as illustrated in FIG. 1, the electronic component 120 can be provided as a plurality of electronic components 120. The plurality of electronic components 120 can be housed in the plurality of cavities 112 in such a way that the electrodes 122 of some of the plurality of electronic components 120 and the electrodes 122 of the remaining electronic components 120 can be in opposite directions.

Specifically, as illustrated in FIG. 1, some of the electronic components 120 can be disposed in such a way that the electrodes 122 can face an upper surface of the dielectric core substrate 110, and the remaining electronic components 120 can be disposed in such a way that the electrodes 122 can face a lower surface of the dielectric core substrate 110.

In this case, as illustrated in FIG. 1, the thickness t1 of the dielectric core substrate 110 can be the same as the thickness t2 of the electronic component 120 including the electrodes 122. As such, since the thickness t1 of the dielectric core substrate 110 is substantially the same as the thickness t2 of the electronic component 120, the upper surface and lower surface of the electronic component 120 can be formed on the same planar surfaces as the upper surface and lower surface of the dielectric core substrate 110, respectively. Accordingly, the insulation layer 130 can be formed on the dielectric core substrate 110 in a uniform height. Therefore, the via 140 and the first circuit pattern 150, etc. can be formed more finely without error.

As illustrated in FIG. 1, the insulation layer 130 can be formed on both surfaces of the dielectric core substrate 110. The insulation layer 130 can be made of, for example, prepreg or ABF (Ajinomoto Build-up Film) and stacked on both surfaces of the dielectric core substrate 110 by using, for example, a vacuum press. Meanwhile, the insulation layer 130 having a copper film formed on one surface thereof can also be stacked on the dielectric core substrate 110.

As illustrated in FIG. 1, the via 140 can be formed in the insulation layer 130 in such a way that the via 140 can be electrically connected to the electrode 122 of the electronic component 120. The via 140 can be formed by filling the inside of a via hole that is formed in the insulation layer 130 in accordance with the position of the electrode 122 with a conductive substance by way of, for example, plating.

As illustrated in FIG. 1, the first circuit pattern 150 can be formed in the insulation layer 130 in such a way that the first circuit pattern 150 can be electrically connected to the via 140. The first circuit pattern 150 can be simultaneously formed with the via 140 in a plating process for forming the via 140. Alternatively, if a copper film is already formed on the insulation layer 130, as described above, some portions of the copper film can be removed by way of etching so that the first circuit pattern 150 can be formed.

As illustrated in FIG. 1, a build-up layer 160, which can be and made of, for example, ABF, can be formed on the insulation layer 130. Then, the second circuit pattern 170 that is formed in such a way that the second circuit pattern 170 is electrically connected to the first circuit pattern 150 can be formed on the build-up layer 160, as illustrated in FIG. 1. In this case, the second circuit pattern 170 can be electrically connected to the first circuit pattern 150 through a via that is formed in the build-up layer 160.

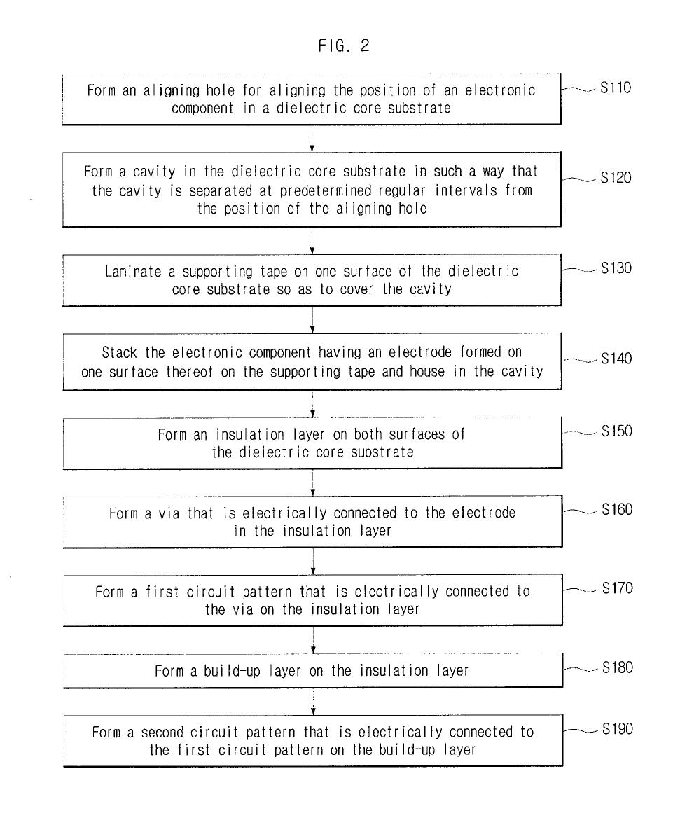

Below, an embodiment of a method of manufacturing an electronic component embedded printed circuit board 200 in accordance with another aspect of the present invention will be described by referring to FIGS. 2 to 11.

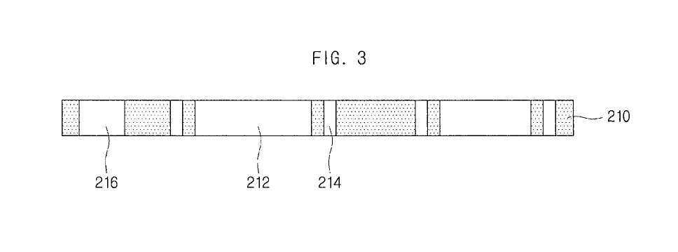

FIG. 2 is a flow diagram illustrating an embodiment of a manufacturing method of an electronic component embedded printed circuit board 200 in accordance with another aspect of the present invention, and FIGS. 3 to 11 are cross-sectional views illustrating each respective manufacturing process of an embodiment of a manufacturing method of the electronic component embedded printed circuit board 200 in accordance with another aspect of the present invention.

In this embodiment, as illustrated in FIG. 2, the method of manufacturing the electronic component embedded printed circuit board 200 includes forming an aligning hole 214 in a dielectric core substrate 210 (S110), forming a cavity 212 in the dielectric core substrate 210 (S120), laminating a supporting tape 280 on one surface of the dielectric core substrate 210 (S130), housing an electronic component 220 having an electrode 222 formed on one surface thereof in the cavity 212 (S140), forming an insulation layer 230 respectively on both surfaces of the dielectric core substrate 210 (S150), forming a via 240 in the insulation layer 230 (S160), forming a first circuit pattern 250 on the insulation layer 230 (S170), forming a build-up layer 260 on the insulation layer 230 (S180) and forming a second circuit pattern 270 on the build-up layer 260 (S190).

In this embodiment, since the dielectric core substrate 210 on which no copper layer is formed is used as a core layer, the wiring pattern layer that is unnecessarily thick as a result of using the conventional core layer stacked with a copper layer can be omitted. Accordingly, the manufacturing process can be simplified, and the yield can be improved.

Below, each respective process of the present embodiment will be described in more detail by referring to FIGS. 2 to 11.

First, the aligning hole 214, which is for aligning the position of the electronic component 220, is formed in the dielectric core substrate 210 (S110), as illustrated in FIG. 3, and then the cavity 212 is formed in the dielectric core substrate 210 in such a way that the cavity 212 is separated at predetermined regular intervals from the position of the aligning hole 214 (S120). The above processes will be further described below.

First, the aligning hole 214 is formed in the dielectric core substrate 210. The aligning hole 214 can be pre-formed in the dielectric core substrate 210 in order to align the positions of the cavity 212 and the electronic component 220. Here, as illustrated in FIG. 3, a panel hole 216 can also be formed in the dielectric core substrate 210. The panel hole 216 can be used to align the electronic component 220 and the dielectric core substrate 210, etc.

Then, the cavity 212 is formed at predetermined regular intervals from the position of the aligning hole 214, and the cavity 212 can be provide as a plurality of cavities 212 in accordance with the number of the electronic component 220 to be embedded.

By setting the position of the cavity 212 with respect to the position of the aligning hole 214, the position of the cavity 212 can be precisely adjusted. Accordingly, the location accuracy of the electronic component 220 to be housed in the cavity 212 can be also improved.

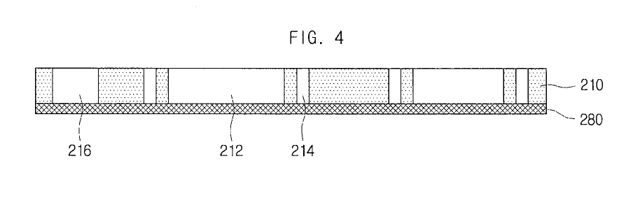

Next, as illustrated in FIG. 4, the supporting tape 280 is laminated on one surface of the dielectric core substrate 210 so as to cover the cavity 212 (S130). The supporting tape 280 can be laminated on a lower surface of the dielectric core substrate 210 in order to support the electronic component 220. Accordingly, since the electronic component 220 aligned in accordance with the positions of the aligning hole 214 and the cavity 212 can be temporarily fixed on the supporting tape 280, the insulation layer 230 can be later formed more readily on the dielectric core substrate 210. When the insulation layer 230 is formed, the alignment of the electronic component 220 can be maintained constant, and thus the location accuracy of the electronic component 220 can be better improved.

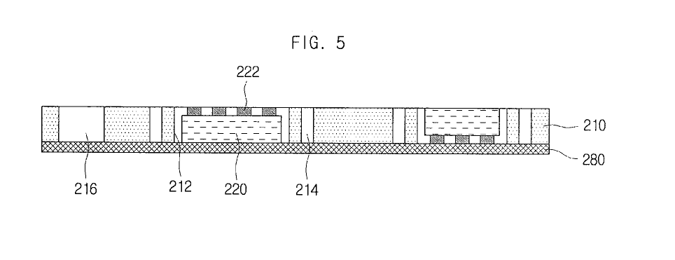

Next, as illustrated in FIG. 5, the electronic component 220 having the electrode 222 formed on one surface thereof is stacked on the supporting tape 280 and housed in the cavity 212 (S140). The electronic component 220 can be housed in the cavity 212 by considering the positions of the aligning hole 214 and the cavity 212. Also, as described above, the electronic component 220 can be temporarily fixed on the supporting tape 280.

In this case, the electronic component 220 can be provided as a plurality of electronic components 220 in accordance with the number of the cavities 212. The plurality of electronic components 220 can be housed in the plurality of cavities 212 in such a way that the electrodes 222 of some of the plurality of electronic components 220 and the electrodes 222 of the remaining electronic components 220 can be in opposite directions.

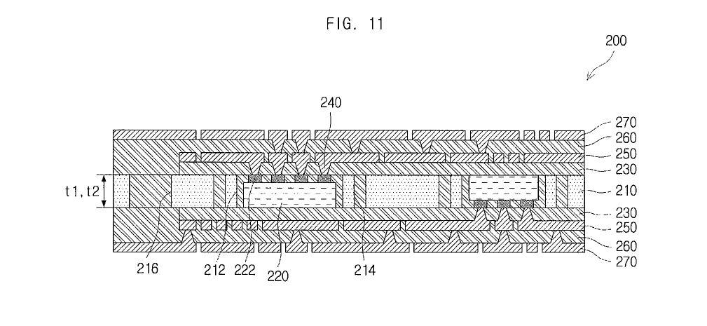

Like the previously described embodiment of the present invention, the thickness t1 (shown in FIG. 11) of the dielectric core substrate 210 can be the same as the thickness t2 (shown in FIG. 11) of the electronic component 220 including the electrodes 222. Therefore, the via 240 and the first circuit pattern 250, etc. can be formed more finely without error in following processes.

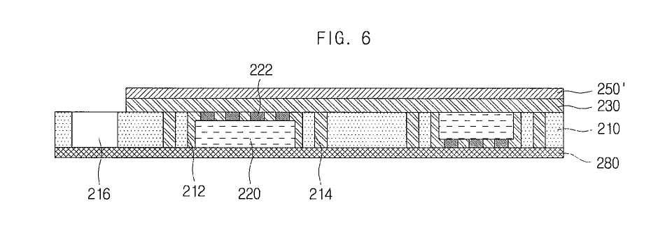

Next, as illustrated in FIGS. 6 to 8, the insulation layer 230 is formed on both surfaces of the dielectric core substrate 210 (S150). This process can be divided into the following processes in order to remove the supporting tape 280 described above.

First, the insulation layer 230 is formed on an upper surface of the dielectric core substrate 210, on which the supporting tape 280 is not stacked, by using, for example, a vacuum press. In this case, as illustrated in FIG. 6, the insulation layer 230 having a copper film 250′ formed thereon can be stacked on the dielectric core substrate 210.

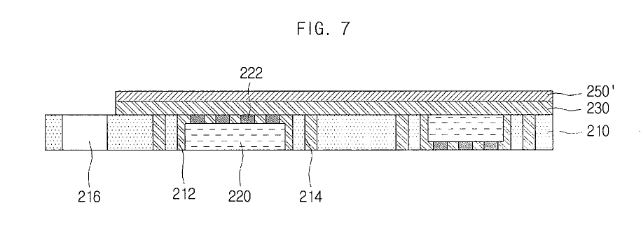

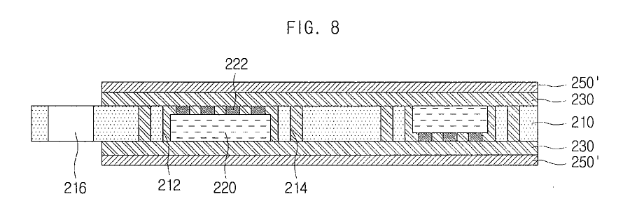

Then, the supporting tape 280 is removed, as illustrated in FIG. 7, and then the insulation layer 230 is formed on the lower surface of the dielectric core substrate 210, from which the supporting tape 280 is removed, by using, for example, a vacuum press. In this case, as illustrated in FIG. 8, the insulation layer 230 having a copper film 250′ formed thereon can be stacked on the dielectric core substrate 210.

Meanwhile, as illustrated in FIGS. 6 to 8, the insulation layer 230 can be stacked on both surfaces of the dielectric core substrate 210 in such a way that the panel hole 216 is not covered. Accordingly, the dielectric core substrate 210 can be aligned more precisely in following processes.

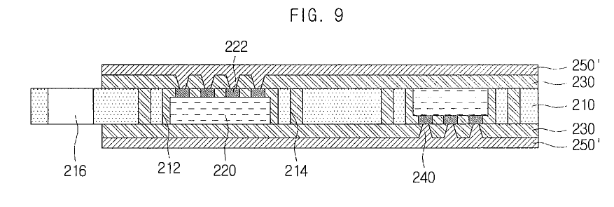

Next, as illustrated in FIG. 9, the via 240 that is electrically connected to the electrode 222 is formed in the insulation layer 230 (S160). As a process for implementing electrical connection to the electrode 222 of the electronic component 220, a via hole can be formed in the insulation layer 230 corresponding to the position of the electrode 222 of the electronic component 220. The via 240 can be formed by filling the via hole with a conductive substance by way of, for example, plating.

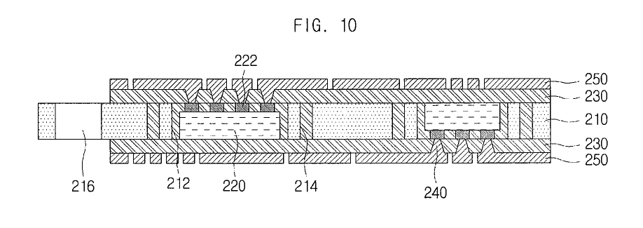

Next, as illustrated in FIG. 10, the first circuit pattern 250 that is electrically connected to the via 240 is formed on the insulation layer 230 (S170). As illustrated in FIGS. 6 to 8, if the insulation layer 230 having the copper film 250′ formed thereon is stacked on the dielectric core substrate 210, some portions of the copper film 250′ can be removed by way of etching to form the first circuit pattern 250.

Although the present embodiment presents that the insulation layer 230 having the copper film 250′ formed thereon is stacked on the dielectric core substrate 210 and then the first circuit pattern 250 is formed by removing some portions of the copper film 250′, it shall be apparent that the case of not having the copper film 250′ stacked on the insulation layer 230 is also included in the scope of the claims of the present invention. In this case, the via 240 and the first circuit pattern 250 can be formed by using, for example, a semi-additive process. The semi-additive process is well known to those of ordinary skill in the art, and thus detailed description will be omitted.

Next, as illustrated in FIG. 11, the build-up layer 260 is formed on the insulation layer 230 (S180), and then the second circuit pattern 270 that is electrically connected to the first circuit pattern 250 is formed on the build-up layer 260 (S190). In order to implement a multi-layered printed circuit board, the build-up layer 260 can be formed on the insulation layer 230 having the first circuit pattern 250 formed thereon so as to cover the first circuit pattern 250.

Then, the second circuit pattern 270 and a via for electrical connection between the first circuit pattern 250 and the second circuit pattern 270 can be formed on the build-up layer 260 by known methods such as tenting, semi-additive process or modified semi-additive process.

While the spirit of the present invention has been described in detail with reference to particular embodiments, the embodiments are for illustrative purposes only and shall not limit the present invention. It is to be appreciated that those skilled in the art can change or modify the embodiment without departing from the scope and spirit of the present invention.

As such, many embodiments other than that set forth above can be found in the appended claims.

What is claimed is:

1. An electronic component embedded printed circuit board comprising:
a dielectric core substrate having a cavity formed therein;
an electronic component being housed in the cavity and having an electrode formed on one surface thereof;
an insulation layer formed on both surface of the dielectric core substrate;
a via formed in the insulation layer such that the via is electrically connected to the electrode; and
a first circuit pattern formed on the insulation layer such that the first circuit pattern is electrically connected to the via.

2. The electronic component embedded printed circuit board of claim 1, wherein:
an aligning hole is formed in the dielectric core substrate to align a position of the electronic component; and
the cavity is formed at predetermined regular intervals from a position of the aligning hole.

3. The electronic component embedded printed circuit board of claim 1, further comprising:
a build-up layer formed on the insulation layer; and
a second circuit pattern formed on the build-up layer in such a way that the second circuit pattern is electrically connected to the first circuit pattern.

4. The electronic component embedded printed circuit board of claim 1, wherein:
the cavity and the electronic component are provided as a plurality of cavities and a plurality of electronic components; and
the plurality of electronic components are housed in the plurality of cavities in such a way that the electrodes of some of the plurality of electronic components and the electrodes of the remaining electronic components are in opposite directions.

5. The electronic component embedded printed circuit board of claim 4, wherein a thickness of the dielectric core substrate is same as a thickness of the electronic component comprising the electrodes.

6. A method of manufacturing an electronic component embedded printed circuit board, the method comprising:
forming a cavity in a dielectric core substrate;
housing an electronic component in the cavity, the electronic component having an electrode formed on one surface thereof;
forming an insulation layer on both surfaces of the dielectric core substrate, respectively;
forming a via in the insulation layer, the via being electrically connected to the electrode; and
forming a first circuit pattern on the insulation layer, the first circuit pattern being electrically connected to the via.

7. The method of claim 6, further comprising, before the forming of the cavity, forming an aligning hole in the dielectric core substrate, the aligning hole being configured to align a position of the electronic component,
wherein the cavity is formed at predetermined regular intervals from a position of the aligning hole.

8. The method of claim 6, further comprising, after the forming of the first circuit pattern:
forming a build-up layer on the insulation layer; and
forming a second circuit pattern on the build-up layer, the second circuit pattern being electrically connected to the first circuit pattern.

9. The method of claim 6, wherein:
the cavity and the electronic component are provided as a plurality of cavities and a plurality of electronic components; and
the plurality of electronic components are housed in the plurality of cavities in such a way that the electrodes of some of the plurality of electronic components and the electrodes of the remaining electronic components are in opposite directions.

10. The method of claim 9, wherein a thickness of the dielectric core substrate is same as a thickness of the electronic component comprising the electrodes.

11. The method of claim 6, further comprising, between the forming of the cavity and the housing of the electronic component, laminating a supporting tape on one surface of the dielectric core substrate so as to cover the cavity,
wherein the housing of the electronic component is performed by stacking the electronic component on the supporting tape.
